(19) United States
(12) Patent Application Publication
(10) Pub. No.: US 2020/0267855 A1
(43) Pub. Date: Aug. 20, 2020

(54) Shockproof Power Bank

(71) Applicant: Tak Kwan CHAN, Hong Kong (HK)

(72) Inventor: Tak Kwan CHAN, Hong Kong (HK)

(21) Appl. No.: 16/373,592

(22) Filed: Apr. 2, 2019

(30) Foreign Application Priority Data
Feb. 20, 2019 (CN) 210910126548.3

(51) Int. Cl. H05K 5/02; H04M 1/02; H05K 5/03

(52) U.S. Cl. CPC H05K 5/0217; H02J 7/0047; H05K 5/03; H04M 1/0202

(57) ABSTRACT

The invention relates to a shockproof power bank which includes a power bank body and a protective cover. The inside of the protective cover is divided into two layers, respectively a spring buffer layer and an air cushion buffer layer. A sleeve is fixedly connected to the inside of the spring buffer layer. A telescopic rod is fixedly connected to the inside of the sleeve. A bottom of the telescopic rod is fixedly connected with a baffle. A spring is provided between a bottom of the telescopic rod and a bottom of the sleeve. The other end of the telescopic rod penetrates the top of the sleeve and is fixedly connected with the protective cover. The bottom of the sleeve is fixedly connected with a connecting rod, and the inner surface of the air cushion buffer layer is fixedly connected with a regular hexagonal airbag. The four adjacent hexagonal airbags are fixedly connected with a diamond airbag. The present invention provides an air cushion buffer layer, a regular hexagonal airbag, a diamond airbag, a pipe, a sleeve, a telescopic rod, a baffle and a spring which solves the problem that the outer surface of the bank power is easy to fall and prevent the internal components from being damaged.

### FIELD OF THE INVENTION

The invention relates to the technical field of shockproof, in particular to a shockproof power bank.

### BACKGROUND

With the changes of the times and the development of society, mobile phones are increasingly entering people's lives. Because mobile phones are easy to carry, they can access the internet at any time and gradually develop into the necessities of people's lives, but people can enjoy charging mobile phones while using mobile phones anytime and anywhere. There has been a problem.

In order to meet the ability to charge the mobile phone anytime and anywhere, the emergence of the power bank solves this problem. At the present stage, the appearance of the power bank undoubtedly alleviates the problem of insufficient power consumption of the smart terminal. The power bank is easy to carry and move which brings great convenience. Power banks are already carried, but the current power banks are generally made of metal casings. When the user accidentally falls or touches the power bank, the outer surface of the power bank is easily deformed. The component is easy to break. In order to avoid the problem that the power bank is easily broken, the present invention provides a shockproof bank power.

### SUMMARY OF THE INVENTION

In view of the deficiencies of the prior art, the present invention provides a shockproof power bank, which solves the problem that the outer surface of the power bank is easily broken and the inner component is broken.

In order to achieve the above objective, the present invention provides the following technical solution. A shockproof power bank includes a power bank body and a protective cover. The inside of the protective cover is divided into two layers, respectively a spring buffer layer and an air cushion buffer layer. A sleeve is fixedly connected to the inside of the spring buffer layer. A telescopic rod is fixedly connected to the inside of the sleeve. A bottom of the telescopic rod is fixedly connected with a baffle. A spring is provided between a bottom of the telescopic rod and a bottom of the sleeve. The other end of the telescopic rod penetrates the top of the sleeve and is fixedly connected with the protective cover. The bottom of the sleeve is fixedly connected with a connecting rod, and the inner surface of the air cushion buffer layer is fixedly connected with a regular hexagonal airbag. The four adjacent hexagonal airbags are fixedly connected with a diamond airbag. The adjacent regular hexagonal airbag and the diamond airbag are fixedly connected by a gas pipe. The upper surface of the air cushion buffer layer is fixedly connected with the connecting rod. The lower surface of the air cushion buffer layer is fixedly connected to the power bank body. The side surface of the protective cover is provided with an input port, and the side surface of the protective cover is provided with an output port. The other side of the protective cover is provided with an illumination opening.

Preferably, the protective cover is made of rubber.

Preferably, the elastic structure is connected to a corner of the connecting rod.

Preferably, the distance between the connecting rod and the power bank body and the protective cover is 6 mm.

The present invention provides the following technical effect.

(1) The present invention provides an air cushion buffer layer, a regular hexagonal airbag, a diamond airbag, and a pipe. When the connecting rod is subjected to a force collision, the regular hexagonal airbag and the diamond airbag are connected by a pipe, and the force is dispersed and relieved. It can protect the bank power body and solve the problem that the outer surface of the bank power is easy to fall and prevent the internal components from being damaged.

(2) The present invention provides a sleeve, a telescopic rod, a baffle and a spring. When the protective cover is subjected to an external force, the telescopic rod will be telescoped in the sleeve, and the baffle fixedly attached to the bottom of the telescopic rod will push the spring to play a buffering role, which solves the problem that the outer surface of the power bank is easy to fall and prevent the internal components from being damaged.

### BRIEF DESCRIPTION OF THE DRAWINGS

The invention is illustrated by the following figures and embodiments.

FIG. 1 shows a front sectional view of the present invention.

FIG. 2 shows a front view of an air cushion buffer layer of the present invention.

FIG. 3 shows a front view of a spring buffer layer of the present invention.

The reference numbers of the figures are as follows:

1: power bank body; 2: protective cover; 3: spring buffer layer; 4: air cushion buffer layer; 41: regular hexagonal airbag; 42: diamond airbag; 43: pipe; 5: sleeve; 51: telescopic rod; 52: baffle; 53: spring; 6: connecting rod; 7: input port; 8: output port; 9: illumination port.

### DETAILED DESCRIPTION

The invention is illustrated in accordance with figures. The figures as simplified diagrams demonstrate the basic structures of the apparatus of embodiments of the invention. Thus, the invention is not limited to the figures.

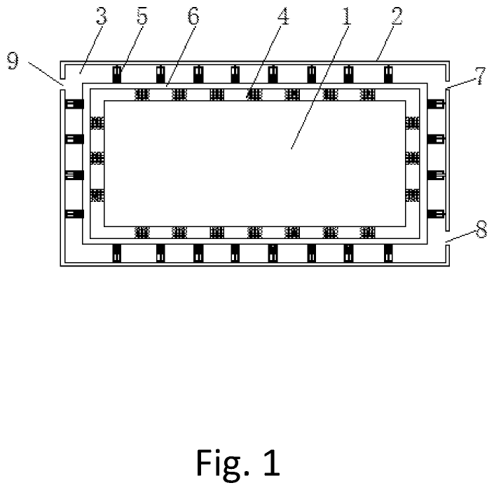

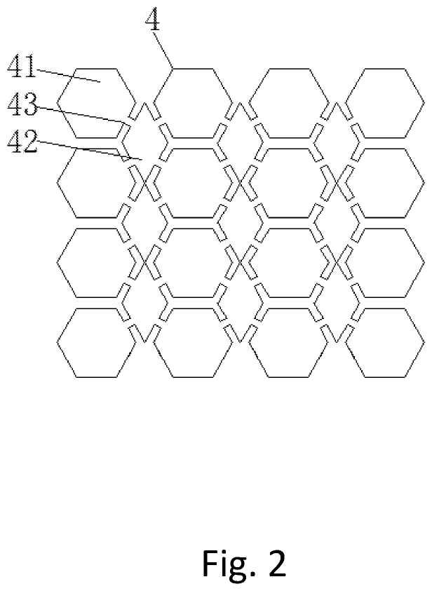

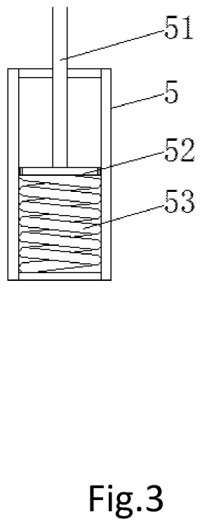

Referring to FIGS. 1-3, the present invention provides the following technical solution. A shockproof power bank includes a power bank body 1 and a protective cover 2. The protective cover is made of rubber. The inside of the protective cover 2 is divided into two layers, respectively a spring buffer layer 3 and an air cushion buffer layer 4. A sleeve 5 is fixedly connected to the inside of the spring buffer layer 3. A telescopic rod 51 is fixedly connected to the inside of the sleeve 5. A bottom of the telescopic rod 51 is fixedly connected with a baffle 52. A spring 53 is provided between a bottom of the telescopic rod 51 and a bottom of the sleeve 5. The other end of the telescopic rod 51 penetrates the top of the sleeve 5 and is fixedly connected with the protective cover 2. The bottom of the sleeve 5 is fixedly connected with a connecting rod 6. The elastic structure is connected to a corner of the connecting rod 6. The distance between the connecting rod 6 and the power bank body 1 and the protective cover 2 is 6 mm. When the protective cover 2 is subjected to an external force, the telescopic rod 51 fixedly connected to the protective cover 2 will be telescoped in the sleeve, and the baffle 52 fixedly attached to the bottom of the telescopic rod 51 will push the spring 53 to play a buffering role. The inner surface of the air cushion buffer layer 4 is fixedly connected with a regular hexagonal airbag 41. The four adjacent hexagonal airbags 41 are fixedly connected with a diamond airbag 42. The adjacent regular hexagonal airbag 41 and the diamond airbag 42 are fixedly connected by a gas pipe 43. The upper surface of the air cushion buffer layer 4 is fixedly connected with the connecting rod 6. When the connecting rod 6 is subjected to a force collision, the regular hexagonal airbag 41 and the diamond airbag 42 are connected by a pipe 43, and the force is dispersed and relieved. It can protect the bank power body 1. The lower surface of the air cushion buffer layer 4 is fixedly connected to the power bank body 1. The side surface of the protective cover is provided with an input port 7, and the side surface of the protective cover 2 is provided with an output port 8. The other side of the protective cover 2 is provided with an illumination opening 9. The input port 7 is for charging the power bank body 1, and the output port 8 is used for charging the mobile phone through the connecting line, and the illumination port 9 is convenient for the user at night.

The present invention provides an air cushion buffer layer 3, a regular hexagonal airbag 41, a diamond airbag 42, a pipe 43, a sleeve 5, a telescopic rod 51, a baffle 52 and a spring 53 which solves the problem that the outer surface of the bank power is easy to fall and prevent the internal components from being damaged.

It should be noted that, in this context, relational terms such as first and second are used merely to distinguish one entity or operation from another entity or operation, and do not necessarily require or imply these entities or operations. There is any such actual relationship or order between them. Furthermore, the term “comprises” or “comprising” or “includes” or any other variations thereof is intended to encompass a non-exclusive inclusion, such that a process, method, article, or device that comprises a plurality of elements includes not only those elements but also other elements, or elements that are inherent to such a process, method, item, or device.

The exemplary embodiments of the present invention are thus fully described. Although the description referred to particular embodiments, it will be clear to one skilled in the art that the present invention may be practiced with variations of these specific details. Hence this invention should not be construed as limited to the embodiments set forth herein.

What is claimed is:

1. A shockproof power bank, comprising: a power bank body 1 and a protective cover 2, wherein the inside of the protective cover 2 is divided into two layers, respectively a spring buffer layer 3 and an air cushion buffer layer 4; a sleeve 5 is fixedly connected to the inside of the spring buffer layer 3; a telescopic rod 51 is fixedly connected to the inside of the sleeve 5; a bottom of the telescopic rod 51 is fixedly connected with a baffle 52; a spring 53 is provided between a bottom of the telescopic rod 51 and a bottom of the sleeve 5; the other end of the telescopic rod 51 penetrates the top of the sleeve 5 and is fixedly connected with the protective cover 2; the bottom of the sleeve 5 is fixedly connected with a connecting rod 6, and the inner surface of the air cushion buffer layer 4 is fixedly connected with a regular hexagonal airbag 41; the four adjacent hexagonal airbags 41 are fixedly connected with a diamond airbag 42; the adjacent regular hexagonal airbag 41 and the diamond airbag 42 are fixedly connected by a gas pipe 43; the upper surface of the air cushion buffer layer 4 is fixedly connected with the connecting rod 6; the lower surface of the air cushion buffer layer 4 is fixedly connected to the power bank body 1; the side surface of the protective cover 2 is provided with an input port 7, and the side surface of the protective cover 2 is provided with an output port 8; the other side of the protective cover 2 is provided with an illumination opening 9.

2. The shockproof power bank of claim 1, wherein the protective cover is made of rubber.

3. The shockproof power bank of claim 1, wherein the elastic structure is connected to a corner of the connecting rod 6.

4. The shockproof power bank of claim 1, wherein the distance between the connecting rod 6 and the power bank body 1 and the protective cover 2 is 6 mm.
